(19) United States
(12) Patent Application Publication
(10) Pub. No.: US 2011/0254114 A1
(43) Pub. Date: Oct. 20, 2011

(54) MAGNETORESISTIVE EFFECT ELEMENT

(76) Inventors: Makoto Nagamine, Komae-shi (JP); Keiji Hosotani, Sagamihara-shi (JP); Hisanori Aikawa, Yokohama-shi (JP); Tomomasa Ueda, Yokohama-shi (JP); Sumio Ikegawa, Musashino-shi (JP)

(21) Appl. No.: 13/172,516

(22) Filed: Jun. 29, 2011

Related U.S. Application Data
(63) Continuation of application No. 12/100,097, filed on Apr. 9, 2008.

(30) Foreign Application Priority Data
Apr. 11, 2007 (JP) 2007-104161

(51) Int. Cl. H01L 29/82

(52) U.S. Cl. 257/421; 257/E21.323

(57) ABSTRACT

A magnetoresistive effect element includes a first ferromagnetic layer formed above a substrate, a second ferromagnetic layer formed above the first ferromagnetic layer, an insulating layer interposed between the first ferromagnetic layer and the second ferromagnetic layer and formed of a metal oxide, and a first nonmagnetic metal layer interposed between the insulating layer and the second ferromagnetic layer and in contact with a surface of the insulating layer on the side of the second ferromagnetic layer, the first nonmagnetic metal layer containing the same metal element as the metal oxide.

### CROSS-REFERENCE TO RELATED APPLICATIONS

This application is a continuation of and claims the benefit of priority under 35 U.S.C. §120 from U.S. Ser. No. 12/100,097 filed Apr. 9, 2008, and claims the benefit of priority under 35 U.S.C. §119 from Japanese Patent Application No. 2007-104161 filed Apr. 11, 2007, the entire contents of each of which are incorporated herein by reference.

### BACKGROUND OF THE INVENTION

1. Field of the Invention

The present invention relates to a magnetoresistive effect element having an insulating layer and a metal layer between two ferromagnetic layers, a fabrication method thereof, a magnetic memory device provided with the magnetoresistive effect element and a fabrication method thereof.

2. Description of the Related Art

A magnetoresistive random access memory (MRAM) uses a magnetoresistive effect element having a tunneling magnetoresistive (TMR) effect in a cell unit for storing information. This magnetoresistive effect element is, for example, a magnetic tunnel junction (MTJ) element having a structure with an insulating layer (referred to as a tunnel barrier layer) inserted between two ferromagnetic layers.

The MTJ element for MRAM is used as a fixed magnetization layer in which the direction of magnetization of one of the two ferromagnetic layers holding the tunnel barrier layer is fixed not to change, while the other ferromagnetic layer is used as a memory layer with the direction of magnetization thereof easily reversed. The information can be stored by setting the state of the fixed magnetization layer and the memory layer parallel and antiparallel with each other in the direction of magnetization in correspondence with “0” and “1” of the binary notation.

In recent years, it has been pointed out that the use of MgO as a tunnel barrier layer can produce the MR ratio (magneto-resistance ratio) of several hundred %. The reason is considered to be that the lattice constant matches between the MgO (001) crystal at 45° and the Fe (001) crystal, and a magnetic layer, MgO and a magnetic layer are stacked in that order as a crystal structure.

Koji Tsunekawa, David D. Djayaprawira, Motonobu Nagai, Hiroki Maehara, Shinji Yamagata, Naoki Watanabe, Shinji Yuasa, Yoshishige Suzuki, and Koji Ando, APPLIED PHYSICS LETTERS, Vol. 87, No. 072503 (2005) (Nonpatent Document 1), for example, reports that in the case where Mg is arranged under MgO to form a film structure of Mg/MgO as a tunnel barrier layer, the MR ratio is improved in the area having a thin MgO and a low barrier resistance. The mere arrangement of Mg under MgO, however, cannot achieve the required life length before dielectric breakdown of the tunnel barrier.

U.S. Pat. No. 6,841,395, on the other hand, proposes to reduce the barrier resistance and improve the MR ratio by forming an oxygen-mixed metal layer after forming a pure metal layer followed by the processing with oxygen gas and thus preventing the oxidation of an underlying magnetic layer. In this method, however, extraneous oxygen atoms are generated in the oxygen-mixed metal layer above the tunnel barrier layer. Therefore, the passing conduction electrons are trapped to cause the likelihood of dielectric breakdown, or oxygen atoms are dispersed above the tunnel barrier layer at the time of annealing after the film-forming process thereby to oxidate the magnetic layer in the neighborhood of the boundary between the upper magnetic layer and MgO, resulting in increase in barrier resistance or decrease in MR ratio.

Also, U.S. Pat. No. 6,347,049 proposes a method in which a laminate barrier layer of different compounds such as MgO/Al₂O₃ is formed to prevent pinholes from being formed in the tunnel barrier layer and to improve the MR ratio with a low barrier resistance. In the case where different compounds are stacked with a very thin tunnel barrier layer not thicker than 1 nm required in the future, however, the lattice matching of the magnetic layer/tunnel barrier layer/magnetic layer would be disrupted, and a high MR ratio required in the future for the MRAM cannot be obtained.

Further, U.S. Patent Application No. 2004/0109347 proposes an example of a method related to the control of the boundary between MgO and the magnetic layer, in which the tunnel barrier layer having a low barrier resistance of not higher than 1.5 eV is used to suppress the leak current for a low applied voltage and supply a comparatively large current for a high applied voltage. Nevertheless, neither a specific method to form the tunnel barrier layer nor a specific method to control the boundary to reduce the barrier resistance is disclosed.

As described above, the conventional magnetoresistive effect element and the conventional fabrication method thereof fail to take the control of the boundary between the tunnel barrier layer and the magnetic layer sufficiently into consideration. As a result, the suppression of the progress of the dielectric breakdown with the energy release of the conduction electrons and the improvement in the MR ratio due to the prevention of oxidation of the magnetic layer are insufficient, thereby reducing the life length before dielectric breakdown and the MR ratio.

### BRIEF SUMMARY OF THE INVENTION

A magnetoresistive effect element according to a first aspect of the present invention comprises: a first ferromagnetic layer formed above a substrate; a second ferromagnetic layer formed above the first ferromagnetic layer; an insulating layer interposed between the first ferromagnetic layer and the second ferromagnetic layer and formed of a metal oxide; and a first nonmagnetic metal layer interposed between the insulating layer and the second ferromagnetic layer and in contact with a surface of the insulating layer on the side of the second ferromagnetic layer, the first nonmagnetic metal layer containing the same metal element as the metal oxide.

A magnetoresistive effect element manufacturing method according to a second aspect of the present invention comprising: forming a first ferromagnetic layer above a substrate; depositing an insulating layer formed of a metal oxide above the first ferromagnetic layer; forming a first nonmagnetic metal layer containing the same metal element as the metal oxide on the insulating layer; and forming a second ferromagnetic layer on the first nonmagnetic metal layer.

### BRIEF DESCRIPTION OF THE SEVERAL VIEWS OF THE DRAWING

FIGS. 1A to 1D are diagrams for explaining dependency of a barrier resistance on a stress application time under a constant voltage stress of a tunnel barrier layer according to first and second reference examples of the invention;

FIG. 2 is a sectional view showing a structure in the neighborhood of a memory cell of a magnetoresistive effect element according to an embodiment of the invention;

FIG. 3 is a detailed sectional view showing the magnetoresistive effect element of FIG. 2;

FIG. 4 is a diagram showing film-forming conditions in a fabrication process of the magnetoresistive effect element according to an embodiment of the invention;

FIGS. 5A to 5C are sectional views showing the fabrication process in a first example of the method of fabricating the magnetoresistive effect element according to an embodiment of the invention;

FIGS. 6A to 6F are sectional views showing the fabrication process in a second example of the method of fabricating the magnetoresistive effect element according to an embodiment of the invention;

FIGS. 7A to 7D are sectional views showing the fabrication process of a magnetic memory device having the magnetoresistive effect element according to an embodiment of the invention;

FIG. 8A is a diagram showing conditions used to check dependency of a thickness of Mg on MgO on an MR ratio and a life length before dielectric breakdown of the magnetoresistive effect element according to an embodiment of the invention;

FIG. 8B is a diagram showing the change in the MR ratio with the change in the film thickness of Mg on MgO from 0 to 2.0 nm based on the conditions shown in FIG. 8A;

FIG. 8C is a diagram showing the change in the life length before dielectric breakdown with the change in the film thickness of Mg on MgO from 0 to 2.0 nm based on the conditions shown in FIG. 8A;

FIG. 9A is a diagram showing the difference in MR ratio in the film-forming conditions (1) to (8) shown in FIG. 4;

FIG. 9B is a diagram showing the difference in life length before dielectric breakdown in the film-forming conditions (1) to (8) shown in FIG. 4;

FIGS. 10A and 10B are diagrams for explaining the effects of the magnetoresistive effect element according to an embodiment of the invention; and

FIG. 11 is a diagram showing a concentration ratio [Mg]/[O] of a whole intermediate layer according to the first and second reference examples and an embodiment of the invention.

### DETAILED DESCRIPTION OF THE INVENTION

[1] Dependency of Barrier Resistance on Stress Application Time

The present inventors have studied the dependency of the barrier resistance on the stress application time under a constant voltage stress exerted on a tunnel barrier layer of a magnetoresistive effect element (MTJ element). As a result, the present inventors have acquired the knowledge described below.

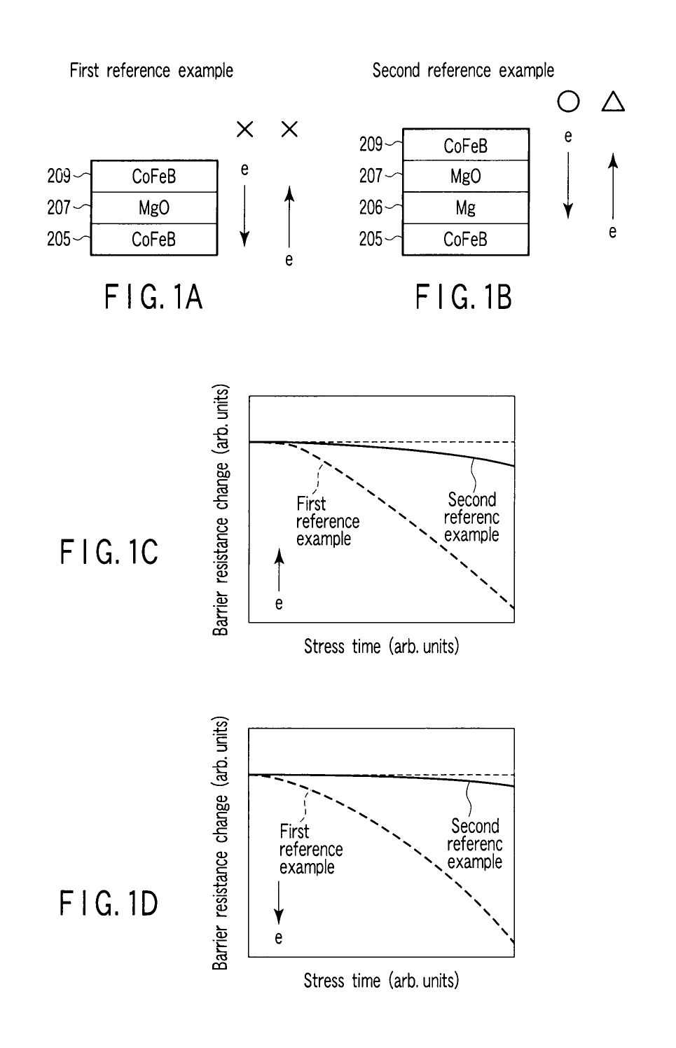

FIGS. 1A to 1D are diagrams for explaining the dependency of the barrier resistance on the stress application time under a constant voltage stress exerted on a tunnel barrier layer according to first and second reference examples of the invention. The direction in which electrons e pass at the time of stress application is shown in each of FIGS. 1A to 1D. In FIGS. 1A and 1B, a semiconductor substrate (not shown) is assumed to exist in the lower part of the page.

As shown in FIG. 1A, according to the first reference example, an insulating layer (tunnel barrier layer) 207 formed of MgO is held by ferromagnetic layers 205, 209 formed of Co—Fe—B. The laminate structure of the first reference example, therefore, is expressed as the ferromagnetic layer 205/insulating layer 207/ferromagnetic layer 209. The term “Co—Fe—B” means an alloy having Co, Fe and B, and in the description that follows, the expression with metal elements connected by hyphens should be interpreted to designate an alloy. The expression “ferromagnetic layer 205/insulating layer 207/ferromagnetic layer 209” means the structure with the ferromagnetic layer 205, the insulating layer 207 and the ferromagnetic layer 209 stacked in that order, and in the description that follows, the laminate structure defined by slashes “/” means a structure of the layers stacked from left to right ones sequentially.

As shown in FIG. 1B, according to the second reference example, the insulating layer 207 formed of MgO is held by the ferromagnetic layers 205, 209 formed of Co—Fe—B, and further, a metal layer 206 formed of Mg is interposed between the ferromagnetic layer 205 and the insulating layer 207. The laminate structure of the second reference example, therefore, is expressed as the ferromagnetic layer 205/metal layer 206/insulating layer 207/ferromagnetic layer 209.

As shown in FIGS. 1C and 1D, according to the second reference example, the change in barrier resistance in the second reference example is smaller than in the first reference example for both cases in which the electrons e pass from upward and downward. As a result, the second reference example is understood to form a tunnel barrier of higher quality more difficult to deteriorate under a constant voltage stress than the first reference example. This is considered due to the fact that the provision of the Mg layer under the MgO layer improves the crystallinity of the boundary between MgO and the lower magnetic layer.

In the second reference example, however, comparison between FIGS. 1C and 1D shows that the change in barrier resistance is greater in the case where the electrons e pass upward as shown in FIG. 1C than in the case where the electrons e pass downward as shown in FIG. 1D. In the second reference example, therefore, it is understood that it is more important to control the boundary between the upper magnetic layer and MgO. Also, taking into consideration that the dielectric breakdown of the tunnel barrier layer is caused by the release of extraneous energy equivalent to the voltage difference on the positive electrode ahead of the passing conduction electrons, it is important to form the boundary between the upper magnetic layer and MgO as a structure strong against the release of the extraneous energy.

Based on this knowledge and in view of the fact that the boundary between the upper magnetic layer and MgO in the tunnel barrier layer of the magnetoresistive effect element should be controlled in a superior state, the progress of the dielectric breakdown due to the energy release of the conduction electrons is suppressed while at the same time preventing the oxidation of the magnetic layer to improve the life length before dielectric breakdown and the MR ratio.

Embodiments of the invention configured based on the aforementioned knowledge will be explained below with reference to the drawings. In the description that follows, common parts are designated by the same reference numerals, respectively.

[2] Magnetoresistive Effect Element and the Surrounding Structure

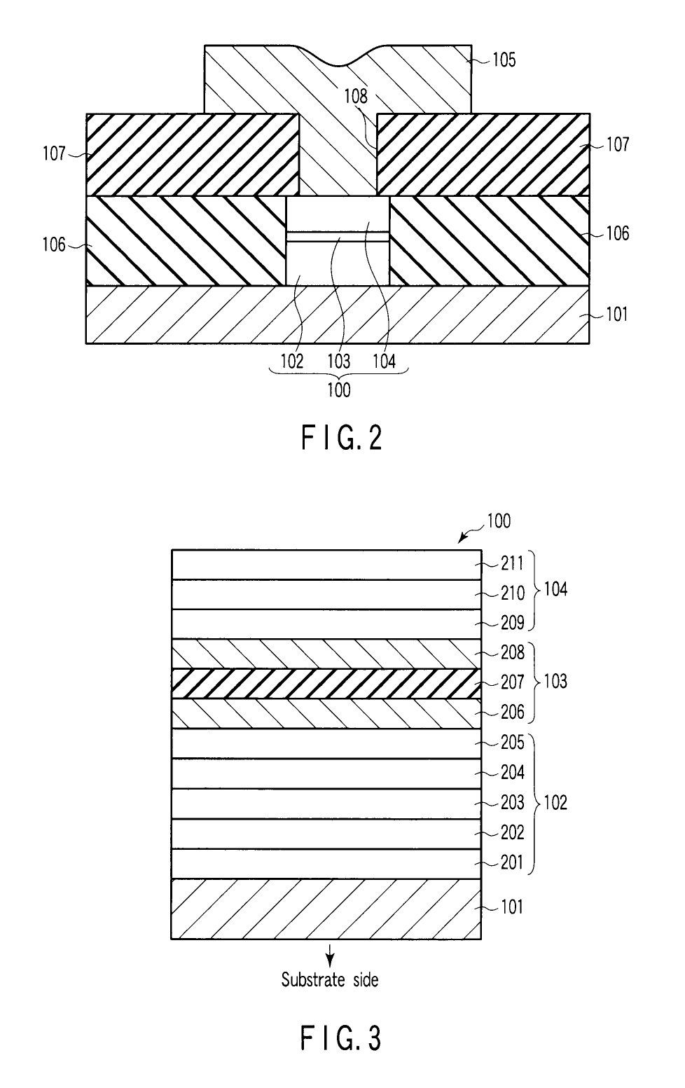

FIG. 2 is a sectional view showing the structure in the neighborhood of a memory cell of the magnetoresistive effect element according to an embodiment of the invention. The magnetoresistive effect element according to an embodiment of the invention and the surrounding structure thereof will be explained below. FIG. 2 is a partly cutaway sectional view of the magnetoresistive effect element used for a magnetic memory device such as a magnetic random access memory.

As shown in FIG. 2, a lower wiring layer 101 is formed above a semiconductor substrate (not shown), and a magnetoresistive effect element 100 is arranged on the lower wiring layer 101. The magnetoresistive effect element 100 includes a fixed magnetization layer 102, a memory layer 104 and an intermediate layer 103 formed between the fixed magnetization layer 102 and the memory layer 104. The magnetoresistive effect element 100 is, for example, an MTJ element.

An upper wiring layer 105 is formed on and connected to the memory layer 104. The upper wiring layer 105 and the lower wiring layer 101 are insulated from each other by insulating layers 106, 107. The upper wiring layer 105 and the lower wiring layer 101 are formed of such a material as Al, Al-Cu, Cu, Ta, W or Ag. The insulating layers 106, 107, on the other hand, are formed of such a material as a silicon oxide film (SiOₓ) or a silicon nitride film (SiNₓ).

The insulating layer 107 is formed with a contact hole 108 reaching the memory layer 104. A conductive member is buried in the contact hole 108. The upper wiring layer 105 and the memory layer 104 are electrically connected to each other by a contact plug formed of this conductive member.

FIG. 3 is a detailed sectional view of the magnetoresistive effect element shown in FIG. 2. The film configuration of the magnetoresistive effect element according to an embodiment of the invention will be explained below.

As shown in FIG. 3, the fixed magnetization layer 102, the intermediate layer 103 and the memory layer 104 of the magnetoresistive effect element 100 each have a multilayer structure. The magnetoresistive effect element 100, therefore, is configured of, for example, a lower wiring connection layer 201, an antiferromagnetic layer 202, a ferromagnetic layer 203, an insertion layer 204, a ferromagnetic layer 205, a metal layer 206, an insulating layer (tunnel barrier layer) 207, a metal layer 208, a ferromagnetic layer 209, a cap layer 210 and an upper wiring connection layer 211.

The fixed magnetization layer 102 has the film structure described below. Specifically, the fixed magnetization layer 102 is formed as a laminate structure including the lower wiring connection layer 201, the antiferromagnetic layer 202, the ferromagnetic layer 203, the insertion layer 204 and the ferromagnetic layer 205.

The lower wiring connection layer 201 is formed of Ta, for example, 5 nm thick. The antiferromagnetic layer 202 is formed of, for example, Pt—Mn 15 nm thick. The ferromagnetic layer 203 is formed of Co—Fe, for example, 2 nm thick. The direction in which the ferromagnetic layer 203 is magnetized is fixed by the antiferromagnetic layer 202. The insertion layer 204 is formed of a nonmagnetic metal such as Ru 1 nm thick. The ferromagnetic layer 205 is formed of Co—Fe—B, for example, 2 nm thick. The ferromagnetic layer 203, the insertion layer 204 and the ferromagnetic layer 205 make up a laminate ferri-pinned structure. The magnetization of the ferromagnetic layer 205 is bonded with the magnetization of the ferromagnetic layer 203 by the insertion layer 204, and therefore, the direction in which the ferromagnetic layer 205 is magnetized is fixed.

The memory layer 104 has the film structure described below. Specifically, the memory layer 104 is formed of a laminate structure having the ferromagnetic layer 209, the cap layer 210 and the upper wiring connection layer 211.

The ferromagnetic layer 209 is formed of Co—Fe—B, for example, 2 nm thick. The direction in which the ferromagnetic layer 209 is magnetized is variable. The cap layer 210 is formed of Ta, for example, 5 nm thick. The upper wiring connection layer 211 is formed of Ru, for example, 7 nm thick, and has the function of protecting the surfaces of the etching mask and the magnetoresistive effect element 100.

The intermediate layer 103 has the film structure described below. Specifically, the intermediate layer 103 has a laminate structure having the metal layer 206, the insulating layer 207 and the metal layer 208.

The insulating layer 207 is desirably formed of any one of a metal oxide, a metal nitride and a metal oxynitride. The metal layers 206, 208 desirably contain the same metal element as the insulating layer 207. The fact that the metal layers 206, 208 and the insulating layer 207 have the same component metal makes it difficult to disrupt the lattice matching in the boundary between the metal layer 206 and the insulating layer 207 and the boundary between the metal layer 208 and the insulating layer 207. Incidentally, the metal element and the metal element unit making up the metal layers 206, 208 are not limited to the same ones as those of the insulating layer 207, but any compound containing the particular metal element as a main component may be used. The metal layers 206, 208 and the insulating layer 207 are nonmagnetic layers.

According to this embodiment, the insulating layer 207 is formed of, for example, MgO, and the metal layers 206, 208 of, for example, Mg. Nevertheless, the insulating layer 207 may alternatively be formed of AlOₓ, AlN, AlON, AlHfOₓ, AlZrOₓ or AlFOₓ, in which case the metal layers 206, 208 are desirably formed of Al.

The metal layers 206 and 208 may be formed of materials different from each other. For example, one of the metal layers 206 and 208 may be formed of a metal unit and the other a metal compound. Also in this case, however, the metal layers 206, 208 desirably contain the same metal element as the insulating layer 207 as a main component.

The insulating layer 207 has a thickness of, for example, 1 nm. The thickness of the metal layer 206, on the other hand, is 0.4 nm, for example. The thickness of the metal layer 208 is, for example, 0.6 nm. The metal layers 206, 208 desirably have the thickness of 0.2 to 2.0 nm as described later.

The metal layers 206, 208 may have the same thickness, or the metal layer 206 may be either thicker or thinner than the metal layer 208. Similarly, the metal layers 206, 208 may have the same thickness as the insulating layer 207. Alternatively, either the metal layers 206, 208 may be thicker than the insulating layer 207 or the insulating layer 207 may be thicker than the metal layers 206, 208.

The surface of the insulating layer 207 near the metal layer 206 is desirably in direct contact with the metal layer 206, and the surface of the insulating layer 207 near the metal layer 208 is desirably in direct contact with the metal layer 208. This is by reason of the fact that the metal layers 206, 208 improve the crystallinity in the boundary between the metal layer 206 and the insulating layer 207 and the boundary between the metal layer 208 and the insulating layer 207, respectively.

In the intermediate layer 103 shown in FIG. 3, the insulating layer 207 is held between the two metal layers 206, 208. Nevertheless, the invention is not limited to this configuration. With a semiconductor substrate (not shown) as a reference, for example, the metal layer 206 under the insulating layer 207 may be omitted, and the intermediate layer 103 may be formed of two layers including the insulating layer 207 and the upper metal layer 208. This leads to the advantage that the extraneous nonmetal element (such as O in MgO) in the insulating layer 207 reacts with the component element of the metal layer 208 and is stabilized as a compound, with the result that generation of a leak spot is suppressed to improve the life length before dielectric breakdown of the insulating layer 207 and the MR ratio. This advantage cannot be sufficiently achieved by the configuration in which the metal layer 206 is formed under the insulating layer 207 as shown in the second reference example (FIG. 1B). This is by reason of the fact that when the insulating layer 207 is formed, the nonmetal component element of the insulating layer 207 bombards and reacts with the underlying metal layer 206 and a greater part of the underlying metal layer 206 is changed to an insulating layer. This is apparent from the fact that as described in Nonpatent Document 1 disclosing the second reference example, the sectional image of MgO under TEM (transmission electron microscope) remains unchanged regardless of whether Mg is present or not under MgO (second and first reference examples). Consequently, the configuration in which the metal layer 208 is formed only above the insulating layer 207 is considered more effective than the configuration in which the metal layer 206 is formed only under the insulating layer 207.

The metal layer 208 “above” the insulating layer 207 is defined as the metal layer 208 deposited after forming the insulating layer 207 in the fabrication process. Thus, this includes a case in which after forming the magnetoresistive effect element 100, the magnetoresistive effect element 100 is turned upside down and attached to another substrate X leading to the final structure in which the metal layer 208 is located “under” the insulating layer 207 with respect to the substrate X.

With regard to the direction of magnetization of the fixed magnetization layer 102 and the memory layer 104, the magnetoresistive effect element 100 may be of either an in-plane magnetization type (parallel magnetization type) in which the direction of magnetization is parallel to the film surface or a perpendicular magnetization type in which the direction of magnetization is perpendicular to the film surface.

The magnetoresistive effect element 100 described above may be modified in various ways. The thickness of each layer making up the magnetoresistive effect element 100, for example, may be appropriately adjusted within the range of 0.1 nm to several tens of nm. Also, each layer of the magnetoresistive effect element 100 may be configured of a material different from the one described above. Further, what is called “the top-pin structure” with the magnetoresistive effect element 100 arranged in the vertically opposite position with respect to the substrate may be formed. Furthermore, the fixed magnetization layer 102 may be formed of a single layer. Also, the memory layer 104 may be formed of a plurality of ferromagnetic layers. Further, a ferromagnetic double-tunnel junction structure having a plurality of tunnel barrier layers may be employed. In the case where one of the two tunnel barrier layers is formed of an insulating layer of MgO and the other tunnel barrier layer of a metal such as Cu, for example, the metal layer 208 may be formed at least on the upper surface (the surface far from the semiconductor substrate) of the tunnel barrier layer formed of an insulating layer.

In the drawings other than FIG. 3, for simplification, the laminate structure from the lower wiring connection layer 201 to the ferromagnetic layer 205 may be designated as a fixed magnetization layer 102, the laminate structure from the metal layer 206 to the metal layer 208 as an intermediate layer 103, and the laminate structure from the ferromagnetic layer 209 to the upper wiring connection layer 211 as a memory layer 104. Also, the laminate structure from the lower wiring connection layer 201 to the upper wiring connection layer 211 as shown in FIG. 3 is hereinafter referred to as a full-stack structure.

[3] Method of Fabricating Magnetoresistive effect Element

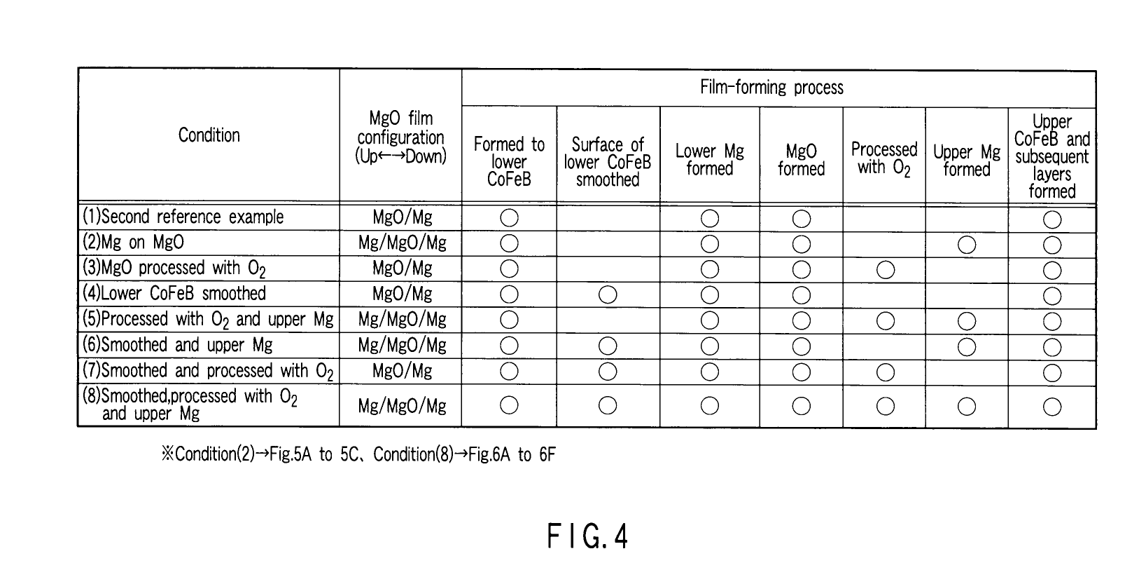

FIG. 4 shows the film-forming conditions in the fabrication process of the magnetoresistive effect element according to an embodiment of the invention. In FIG. 4, “Mg on MgO” or “upper Mg” corresponds to, for example, the metal layer 208 formed of Mg shown in FIG. 3, “MgO” corresponds to, for example, the insulating layer 207 formed of MgO shown in FIG. 3, “lower Mg” corresponds to, for example, the metal layer 206 formed of Mg in FIG. 3, “lower CoFeB” corresponds to, for example, the ferromagnetic layer 205 formed of Co—Fe—B in FIG. 3, and “upper CoFeB” corresponds to, for example, the ferromagnetic layer 209 formed of Co—Fe—B in FIG. 3.

As shown in FIG. 4, eight film-forming conditions are used for forming the magnetoresistive effect element 100. Each round mark “◯” in the film-forming process shown in FIG. 4 indicates the processing step actually executed.

The eight film-forming conditions include (1) second reference example, (2) Mg on MgO, (3) processing MgO with O₂, (4) smoothing the lower CoFeB, (5) processing with O₂, and upper Mg, (6) smoothing, and upper Mg, (7) smoothing and processing with O₂, and (8) smoothing, processing with O₂ and upper Mg.

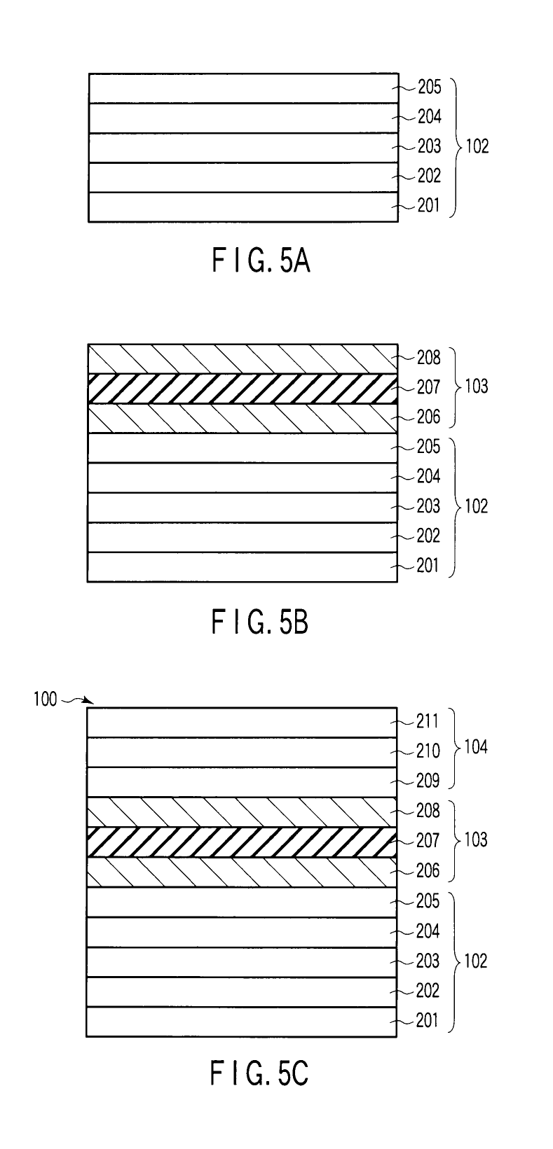

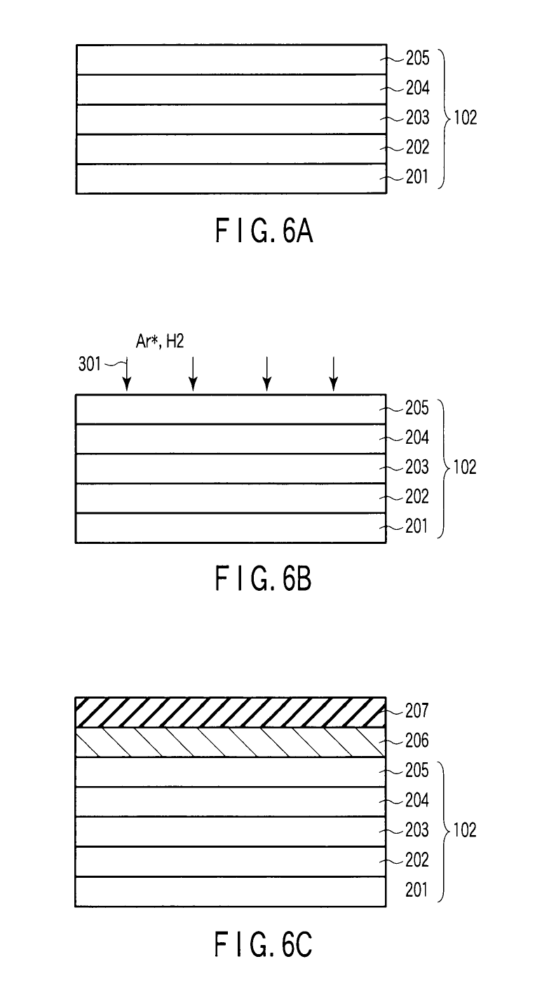

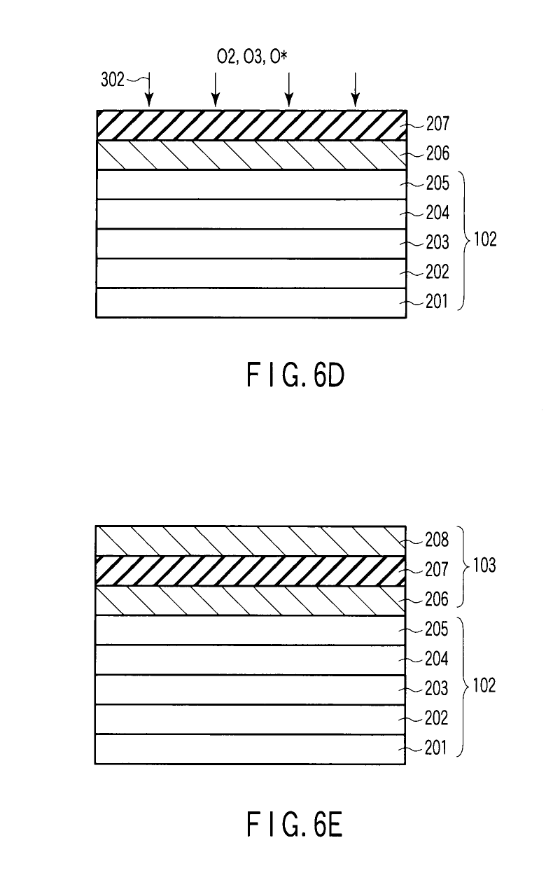

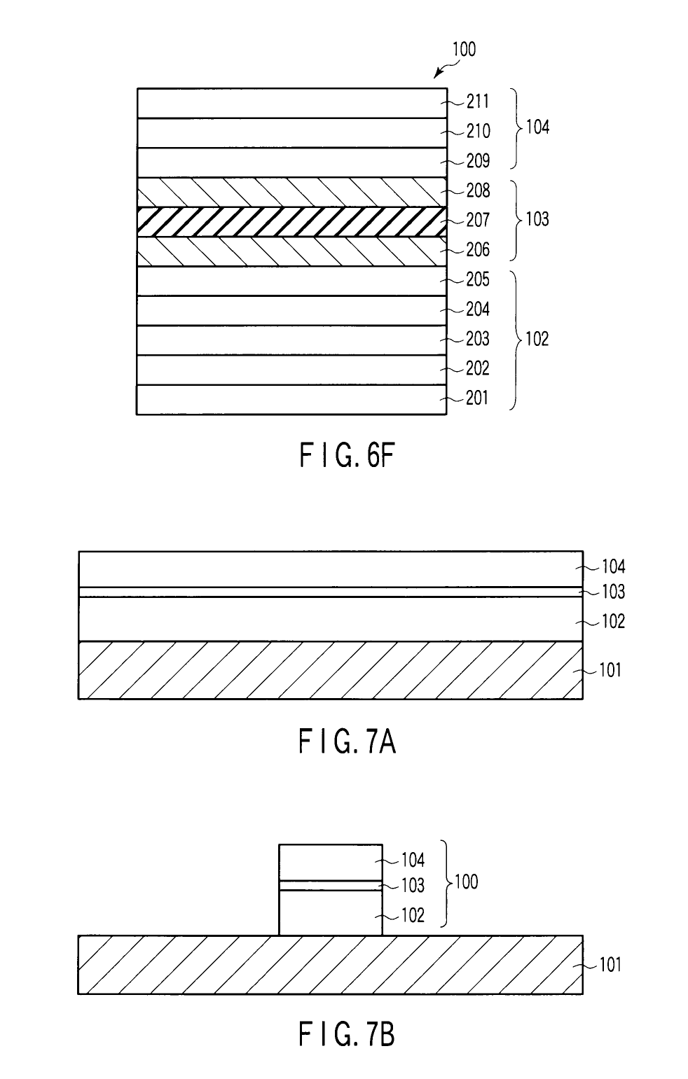

The condition (1) corresponds to the film-forming process for the structure shown in FIG. 1B, and the condition (2) corresponds to the film-forming process shown in FIGS. 5A to 5C. The condition (8) corresponds to the film-forming process shown in FIGS. 6A to 6F. The other conditions correspond to the film-forming conditions lacking the processing steps in any one of FIGS. 6B, 6D and 6E.

Incidentally, the process of forming each layer of the magnetoresistive effect element 100 using sputtering in the example of the fabrication method described below is modifiable, and may use, for example, the vapor deposition, the atomic layer deposition (ALD) or the chemical vapor deposition (CVD).

[3-1] First Example of Fabrication Method

FIGS. 5A to 5C are sectional views showing the fabrication process in the first example of the fabrication method of the magnetoresistive effect element according to one embodiment of the invention. This first example of the fabrication method uses the film-forming condition (2) shown in FIG. 4.

First, as shown in FIG. 5A, the lower wiring connection layer 201 of Ta, the antiferromagnetic layer 202 of Pt—Mn, the ferromagnetic layer 203 of Co—Fe, the insertion layer 204 of Ru and the ferromagnetic layer 205 of Co—Fe—B are formed in that order on the lower wiring layer 101 (not shown). As a result, the fixed magnetization layer 102 having a laminate structure is formed.

Next, as shown in FIG. 5B, the metal layer 206 of Mg, the insulating layer 207 of MgO and the metal layer 208 of Mg are formed on the ferromagnetic layer 205 sequentially. As a result, the intermediate layer 103 having a laminate structure is formed.

Then, as shown in FIG. 5C, the ferromagnetic layer 209 of Co—Fe—B, the cap layer 210 of Ta and the upper wiring connection layer 211 of Ru are formed sequentially on the metal layer 208. As a result, the memory layer 104 having a laminate structure is formed. In this way, the full-stack structure of the magnetoresistive effect element 100 is formed.

In the process shown in FIG. 5B, the insulating film 207 is formed by sputtering in the manner described below.

Specifically, in the case where the insulating layer 207 is an oxide layer, the barrier oxidation process may be performed after the direct sputtering of a compound target (for example, MgO target), the reactive sputtering (for example, O₂ gas introduction) of a metal target (for example, Mg target) or the forming of a metal layer (for example, Mg layer). The barrier oxidation uses an oxygen plasma, an oxygen radial, ozone or oxygen gas atmosphere.

In the case where the insulating layer 207 is a nitride layer, on the other hand, the nitridation atmosphere such as nitrogen plasma, nitrogen radical, nitrogen, ammonia, NO, NO₂ or N₂O may be used for barrier nitridation after reactive sputtering of the metal target or the forming of the metal layer.

In the case where the insulating layer 207 is an oxynitride layer, on the other hand, the atmospheres for the nitridation of a metal oxide layer, the oxidation of a metal nitride layer and the oxynitridation may be used in any appropriate combination.

[3-2] Second Example of Fabrication Method

FIGS. 6A to 6F are sectional views showing the fabrication process according to the second example of the method of fabricating the magnetoresistive effect element according to an embodiment of the invention. This second example of the fabrication method uses the film-forming condition (8) shown in FIG. 4.

First, as shown in FIG. 6A, the lower wiring connection layer 201 of Ta, the antiferromagnetic layer 202 of Pt—Mn, the ferromagnetic layer 203 of Co—Fe, the insertion layer 204 of Ru and the ferromagnetic layer 205 of Co—Fe—B are formed in that order on the lower wiring layer 101 (not shown). As a result, the fixed magnetization layer 102 having a laminate structure is formed.

Next, as shown in FIG. 6B, the surface of the ferromagnetic layer 205 underlying the intermediate layer 103 is smoothed in step 301. This smoothing step 301 smoothes and increases the purity and improves the life length before dielectric breakdown of the intermediate layer 103 formed in the next step.

The smoothing step 301 can be executed by any of the three methods described below. A first method consists in the gas-phase etching, in which the silicon oxide film is etched with argon gas plasma at a low rate of about 2 nm per 60 seconds. A second method involves the gas exposure process, in which by exposure in the gas atmosphere of hydrogen gas or nitrogen gas, for example, the surface condition of the ferromagnetic layer 205 is changed or the surface contamination with water, organic materials, etc. is removed. According to a third method, the crystalline structure of the ferromagnetic layer 205 is changed by the rapid thermal annealing (RTA) by radiation of the lamp light or heating of the substrate (not shown) with the heater. Incidentally, the process parameters such as the type, mixing ratio, pressure and temperature of the processing gas, the discharge output and the processing time for the plasma, if used, may be changed appropriately.

Next, as shown in FIG. 6C, the metal layer 206 of Mg and the insulating layer 207 of MgO are formed sequentially on the smoothed surface of the ferromagnetic layer 205. In the process, the insulating layer 207 can be formed by sputtering according to the same method as the first example of the fabrication method described above.

As shown in FIG. 6D, the surface of the insulating layer 207 is processed with oxygen in step 302. The oxygen processing in step 302 repairs the oxygen atom defect in the insulating layer 207 of MgO and improves the service life before dielectric breakdown of the intermediate layer 103.

In a method of oxygen processing step 302, the surface of the insulating layer 207 is exposed to the oxidation atmosphere of oxygen gas, ozone or oxygen plasma. For example, the insulating layer 207 is exposed for 30 seconds to the oxygen gas atmosphere under the pressure up to 2 Pa. In order to improve the reactivity between the oxidating gas and the oxygen atom defect, the sample may be heated with RTA or heater. In the case where the insulating layer 207 is formed of a metal nitride, the nitridation atmosphere may be used in place of the oxidation atmosphere described above. In the case where the insulating layer 207 is formed of a metal oxynitride, on the other hand, any one of the following methods may be employed: (a) a method in which the oxide film formed by sputtering is exposed to the nitrogen atmosphere, (b) a method in which the nitride film formed by sputtering is exposed to the oxygen atmosphere, and (c) a method in which the oxide film, the nitride film or the metal film formed by sputtering is exposed to the oxynitridation atmosphere. Also, the process parameters such as the type, mixing ratio, pressure and the temperature of the processing gas, the discharge output for the plasma, if used, and the processing time may be appropriately changed.

Next, as shown in FIG. 6E, the metal layer 208 of Mg is formed on the surface of the insulating layer 207 subjected to the oxygen processing 302. As a result, the intermediate layer 103 having a laminate structure is formed.

As shown in FIG. 6F, the ferromagnetic layer 209 of Co—Fe—B, the cap layer 210 of Ta and the upper wiring connection layer 211 of Ru are formed sequentially on the metal layer 208. As a result, the memory layer 104 having a laminate structure is formed. Thus, the full-stack structure of the magnetoresistive effect element 100 is formed.

In this second example of the fabrication method, assume that the insulating layer 207 of MgO originally has many oxygen atoms. The oxygen processing step 302 shown in FIG. 6D leads to the existence of extraneous oxygen atoms in the insulating layer 207. In the case where the heat treatment is carried out under this condition, the extraneous oxygen atoms are bonded with Mg of the metal layer 208, and therefore, the oxygen dispersion to the ferromagnetic layer 209 can be suppressed.

Incidentally, the first and second examples of the fabrication method include the film-forming steps under the conditions (2) and (8) of FIG. 4 corresponding to each other, while the film-forming steps under the other conditions omit one of FIGS. 6B, 6D and 6E in the second example of the fabrication method. Specifically, the condition (1) shown in FIG. 4 omits FIGS. 6B, 6D and 6E in the second example of the fabrication method, the condition (3) shown in FIG. 4 omits FIGS. 6B and 6E in the second example of the fabrication method, the condition (4) shown in FIG. 4 omits FIGS. 6D and 6E in the second example of the fabrication method, the condition (5) shown in FIG. 4 omits FIG. 6B in the second example of the fabrication method, the condition (6) shown in FIG. 4 omits FIG. 6D in the second example of the fabrication method, and the condition (7) shown in FIG. 4 omits FIG. 6E in the second example of the fabrication method.

[4] Method of Fabricating Magnetic Memory Device

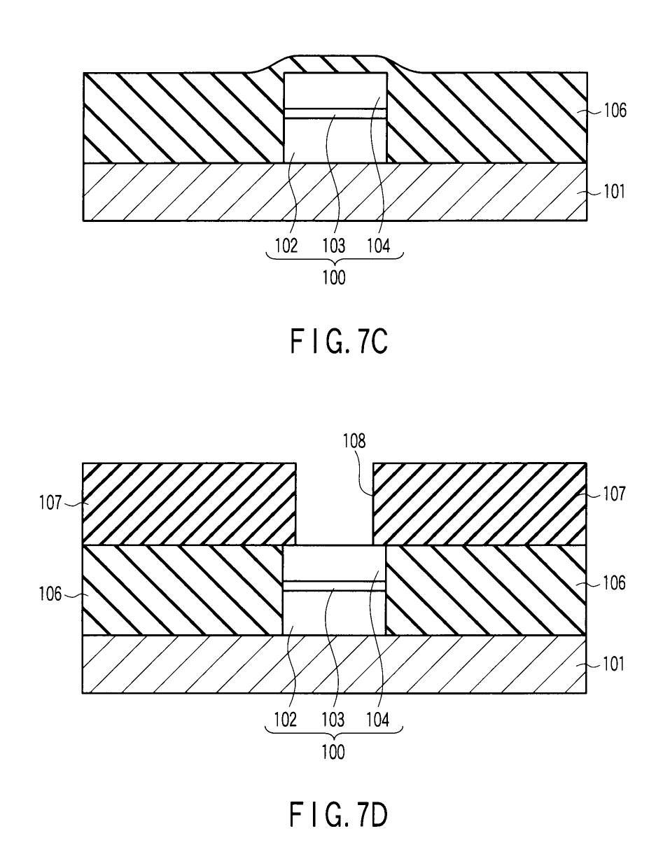

FIGS. 7A to 7D are sectional views showing the method of fabricating a magnetic memory device having the magnetoresistive effect element according to an embodiment of the invention. These drawings correspond to the fabrication steps of the structure shown in the diagram of FIG. 2. Now, an explanation will be given about the fabrication steps of the surrounding structure subsequent to the film-forming process of the magnetoresistive effect element described above.

First, as shown in FIG. 7A, the lower wiring layer 101 is formed above the semiconductor substrate (not shown) by, for example, CVD or sputtering. Next, under any one of the film-forming conditions shown in FIG. 4, the fixed magnetization layer 102, the intermediate layer 103 and the memory layer 104 are formed on the lower wiring layer 101 thereby to form the full-stack structure.

After forming the full-stack structure, the substrate may be annealed, as required, in a magnetic or nonmagnetic field. Instead of the exemplary condition of 360° C., 2 hours and 1 T, the condition including other temperature, time and magnetic field may be used. Also, the RTA heating process may be used.

Next, as shown in FIG. 7B, a mask member (not shown) having a desired planar pattern of the magnetoresistive effect element 100 is formed on the memory layer 104 using, for example, CVD or lithography. Using this mask member, the fixed magnetization layer 102, the intermediate layer 103 and the memory layer 104 are selectively etched by the ion milling process or the reactive ion etching (RIE) process. As a result, the fixed magnetization layer 102, the intermediate layer 103 and the memory layer 104 are processed into a predetermined planar pattern, and the magnetoresistive effect element 100 is formed. After that, the mask member is removed.

The etching process of the fixed magnetization layer 102, the intermediate layer 103 and the memory layer 104 is not limited to the collective processing described above. Alternatively, the etching process may be stopped at the upper surface of the insulating layer 207 making up the intermediate layer 103, for example, and the fixed magnetization layer 102 may not be etched.

Next, as shown in FIG. 7C, the insulating layer 106 is formed by sputtering or CVD in such a manner as to cover the magnetoresistive effect element 100. This insulating layer 106 has the function of protecting the magnetoresistive effect element 100 in the subsequent steps and may be formed of SiO₂ or SiN.

In the next step, a mask member (not shown) having a planar pattern corresponding to that of the lower wiring layer 101 is formed on the insulating layer 106 using CVD or lithography. Next, the insulating layer 106 and the lower wiring layer 101 are selectively etched by the RIE process using the mask member. In the process, the parts located on this side and in the depth through the page of FIG. 7C are etched off, and therefore, the change by the etching is not shown in FIG. 7C. At the time of this etching process, the magnetoresistive effect element 100 is protected by the insulating layer 106.

Next, as shown in FIG. 7D, the insulating layer 107 is formed over the whole surface by, for example, sputtering or CVD. This insulating layer 107 is formed of SiO₂, for example. Then, using the lithography and RIE, the insulating layers 106, 107 are selectively removed. As a result, the internal part of the insulating layer 107 on the magnetoresistive effect element 100 is formed with a contact hole 108 reaching the magnetoresistive effect element 100.

As shown in FIG. 2, a conductive material is buried in the contact hole 108, while at the same time depositing the conductive material on the insulating layer 107 by CVD, for example. Next, the conductive material on the insulating layer 107 is selectively etched by lithography and RIE. As a result, the upper wiring layer 105 is formed.

An alternative method of forming the upper wiring layer 105 may be employed, in which the contact hole 108 is buried with the conductive material and flattened to such an extent as to expose the insulating layer 107 thereby to form a contact plug, after which a film of the conductive material is formed on the insulating layer 107 and the contact plug, followed by etching.

[5] MR Ratio and Life Length before Dielectric Breakdown due to Thickness Change of Mg on MgO

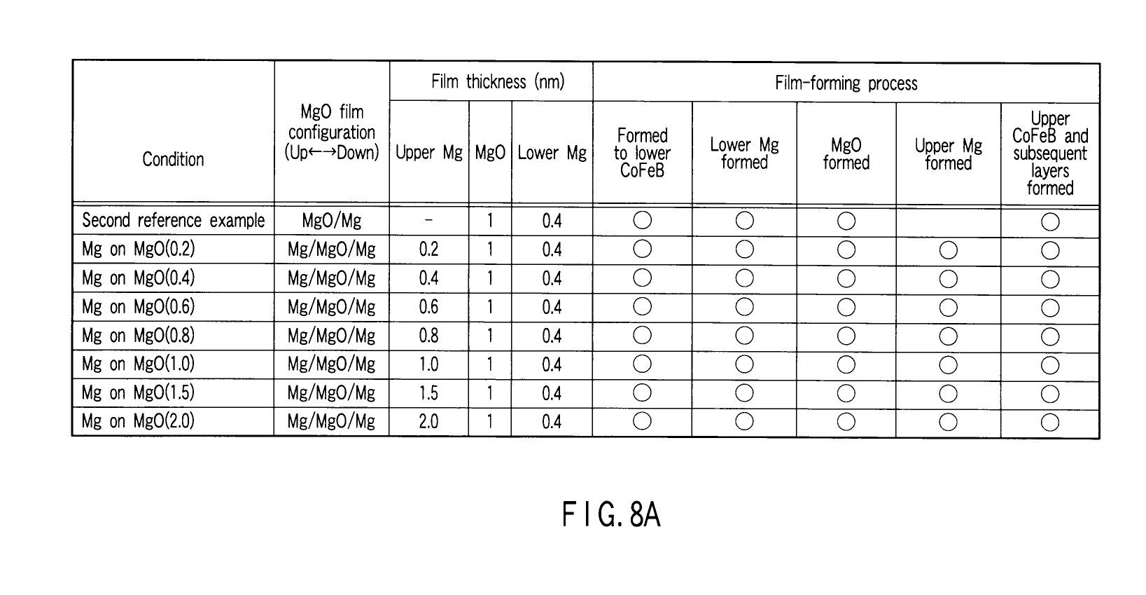

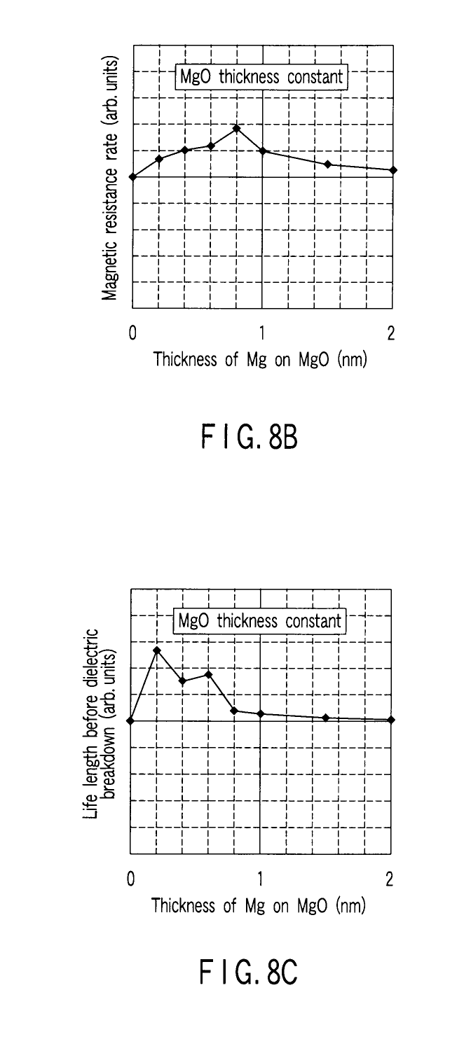

FIGS. 8A to 8C are diagrams for explaining the dependency of the thickness of Mg on MgO on the MR ratio and the life length before dielectric breakdown of the magnetoresistive effect element according to an embodiment of the invention. This case uses the magnetoresistive effect element 100 formed with the metal layer 208 of Mg on the insulating layer 207 of MgO according to the first example of the fabrication method shown in FIGS. 5A to 5C and the magnetoresistive effect element according to the second reference example shown in FIG. 1B. In FIGS. 8A to 8C, “Mg on MgO” or “upper Mg” corresponds to the metal layer 208 of Mg, for example, in FIG. 3, “MgO” to the insulating layer 207 of MgO, for example, in FIG. 3, “lower Mg” to the metal layer 206 of Mg, for example, in FIG. 3, “lower CoFeB” to the ferromagnetic layer 205 of Co—Fe—B, for example, in FIG. 3, and “upper CoFeB” to the ferromagnetic layer 209 of Co—Fe—B, for example, in FIG. 3.

Under the conditions shown in FIG. 8A, the thickness of Mg on MgO is changed to 0.2 nm, 0.4 nm, 0.6 nm, 0.8 nm, 1.0 nm, 1.5 nm and 2.0 nm in that order. The second reference example represents a case in which the thickness of Mg on MgO is 0 nm for lack of the metal layer 208 of Mg. Incidentally, the thickness of MgO is constant at 1 nm, while the thickness of lower Mg constant at 0.4 nm.

FIG. 8B shows the change in MR ratio with the thickness of Mg on MgO changed from 0 to 2.0 nm. As shown in FIG. 8B, the graph is convex upward with the top for Mg on MgO 0.8 nm thick. Specifically, with the thickness zero of Mg on MgO (in the absence of Mg on MgO) as a reference, the MR ratio increases with the increase in thickness of Mg on MgO, and reaches the highest value for the thickness 0.8 nm of Mg on MgO. A further increase in the thickness of Mg on MgO decreases the MR ratio. For the thickness 2.0 nm of Mg on MgO, however, a higher MR ratio can be maintained than for the thickness zero of Mg on MgO.

The graph of FIG. 8B shows the monotonic upward trend of the MR ratio up to the thickness of 0.8 nm in the presence of the upper Mg, and therefore, the MR ratio is considered to be improved even in the case where the thickness of the upper Mg is 0.1 nm.

FIG. 8C shows the change in the life length before dielectric breakdown of the tunnel barrier under a constant voltage stress with the thickness of Mg on MgO changed from 0 to 2.0 nm. As shown in the graph of FIG. 8C, the life length before dielectric breakdown decreases with the increase in the thickness of Mg on MgO from the top for the thickness 0.2 nm of Mg on MgO. In the case where the thickness of Mg on MgO is 2.0 nm, however, a longer life length before dielectric breakdown can be maintained than in the case where the thickness of Mg on MgO is zero.

The result shown in FIGS. 8A to 8C indicates that the following conclusion on the thickness of Mg on MgO is obtained from the viewpoint of the MR ratio and the life length before dielectric breakdown:

The thickness of Mg on MgO is desirably in the range of 0.2 nm to 2.0 nm. In this range, both the MR ratio and the life length before dielectric breakdown can be maintained at a higher level than when Mg on MgO is not formed.

The thickness of Mg on MgO is desirably in the range of 0.4 nm to 1.0 nm. In this range, the highest MR ratio can be maintained. More desirably, the thickness of Mg on MgO is 0.8 nm.

The thickness of Mg on MgO is desirably in the range of 0.2 nm to 0.6 nm. In this range, the longest life length before dielectric breakdown can be maintained. More desirably, the thickness of Mg on MgO is 0.2 nm.

[6] MR Ratio and Life Length before Dielectric Breakdown with Change in Film-Forming Condition

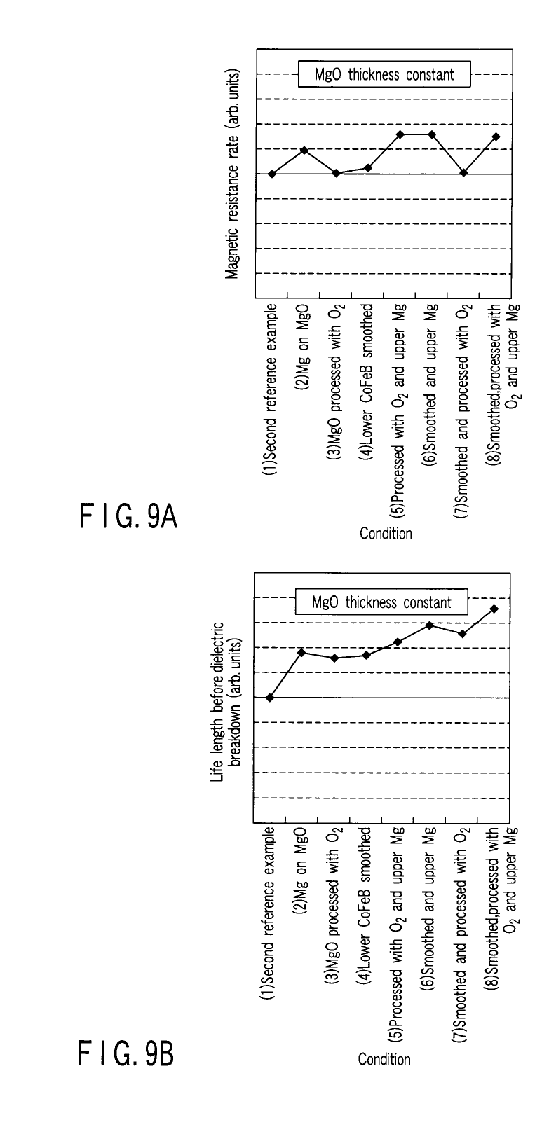

FIGS. 9A and 9B are diagrams for explaining the dependency of the MR ratio and the life length before dielectric breakdown on the film-forming conditions of the magnetoresistive effect element according to an embodiment of the invention. In this case, the film-forming conditions shown in FIG. 4 are used. In FIGS. 9A and 9B, “Mg on MgO” or “upper Mg” corresponds to the metal layer 208 of Mg, for example, in FIG. 3, “MgO” to the insulating layer 207 of MgO, for example, in FIG. 3, and “lower CoFeB” to the ferromagnetic layer 205 of Co—Fe—B, for example, in FIG. 3.

FIG. 9A shows the MR ratio under the film-forming conditions (1) to (8) shown in FIG. 4. As shown in FIG. 9A, it is understood that as compared with the second reference example with the condition (1), the MR ratio is improved in the film-forming process under the conditions (2), (5), (6) and (8). Specifically, the conditions (2), (5), (6) and (8) represent a case in which the Mg film is formed on MgO as well as a case in which “smoothing” and “O₂ processing” are combined. Comparison among the conditions (2), (5), (6) and (8) shows that the MR ratio is higher for the conditions (5), (6) and (8) including at least one of “smoothing” and “O₂ processing” than for the condition (2) including neither “smoothing” nor “O₂ processing”.

FIG. 9B shows the life length before dielectric breakdown of the tunnel barrier under a constant voltage stress for the film-forming conditions (1) to (8) shown in FIG. 4. As shown in FIG. 9B, the life length before dielectric breakdown is improved in the film-forming process under the conditions (2) to (8) than in the second reference example under the condition (1). Specifically, by executing at least one of the three processes including “Mg on MgO”, “smoothing lower CoFeB” and “processing MgO with O₂”, the life length before dielectric breakdown is more improved than in the second reference example in which none of the three processes is executed.

The cause of improvement in the life length before dielectric breakdown under the conditions (2) to (8) is considered as described below.

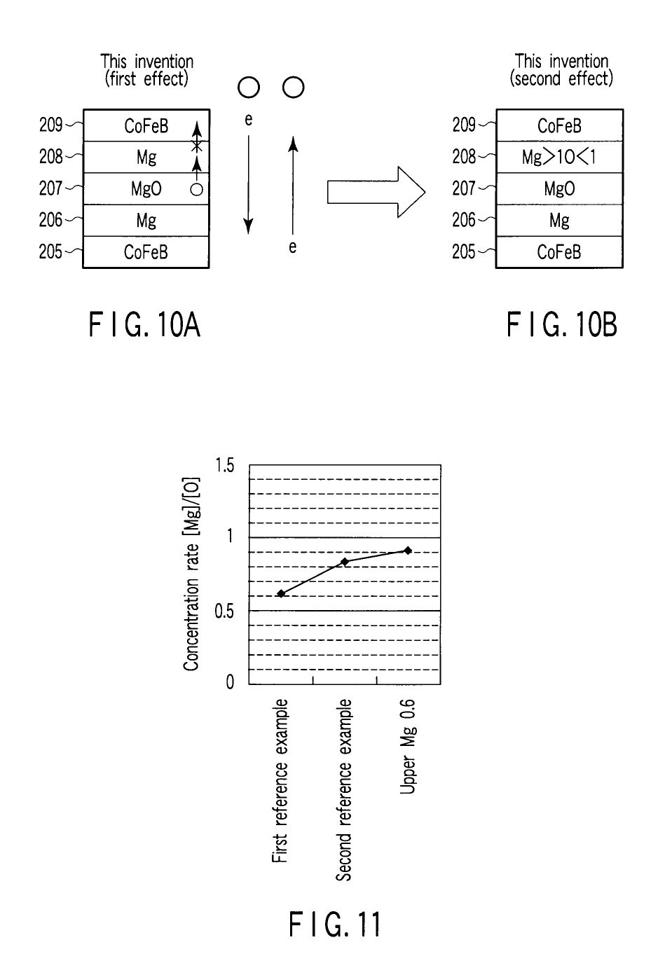

The reason why the life length before dielectric breakdown is improved by “Mg on MgO” will be described later with reference to FIGS. 10A to 10D.

The reason why the life length before dielectric breakdown is improved by “processing MgO with O₂” is that the oxygen atom defect in MgO of the insulating layer 207 is repaired by O atoms of O₂.

The reason why the life length before dielectric breakdown is improved by “smoothing lower CoFeB” is that the insulating layer 207 formed just above the smoothed ferromagnetic layer 205 is smoothed, and therefore, the local concentration of the electric field due to roughness is suppressed.

[7] Effects of Forming Mg on MgO

FIGS. 10A and 10B are diagrams for explaining the effects of forming Mg on MgO of the magnetoresistive effect element according to an embodiment of the invention.

In the magnetoresistive effect element 100, two possible effects are obtained by forming Mg on MgO.

[7-1] First Effect

The first effect is that as shown in FIG. 10A, by forming the metal layer 208 of Mg on the insulating layer 207 of MgO, the ferromagnetic layer 209 is prevented from being oxidated with the diffusion of O atoms into the ferromagnetic layer 209 from the insulating layer 207 at the time of annealing after forming the layers. As a result, the reduction in MR ratio is suppressed while at the same time preventing a trap source from being formed by the energy release from the conduction electrons.

The provision of the metal layer 206 of Mg under the insulating layer 207 of MgO can prevent the oxidation of the ferromagnetic layer 205 with the diffusion of the 0 atoms from the insulating layer 207 to the ferromagnetic layer 205 at the time of annealing after forming the layers.

[7-2] Second Effect

The possible second effect is that as shown in FIG. 10B, the O atoms are diffused from MgO at the time of annealing after forming the metal layer 208 of Mg, and the metal layer 208 changes to a Mg-rich MgO layer. This Mg-rich MgO layer contains more Mg than normal MgO. In the case under consideration, the metal layer 208 has changed to the Mg-rich MgO layer. Nevertheless, the Mg layer can be left on the Mg-rich MgO layer, for example, in the case where the metal layer 208 of Mg is thick or the oxygen concentration in MgO is low.

In view of the fact that the metal layer 208 of Mg changes to the Mg-rich MgO layer as described above, the boundary structure of MgO/magnetic layer is formed, and the trap source due to the energy release from the conduction electrons is prevented from being formed. The insulating layer 207 of MgO supplying O atoms is estimated to be more reduced in effective thickness than before the diffusion of O atoms. Thus, the barrier resistance can be reduced while keeping the boundary structure of the MgO/magnetic layer in satisfactory state.

The specific effects of conversion of the metal layer 208 of Mg into the Mg-rich MgO layer are as follows:

Once the insulating layer (MgO) 207 underlying the metal layer (upper Mg) 208 is deprived of the extraneous O atoms by the metal layer (upper Mg) 208, the concentration of the extraneous atoms liable to be charged negatively is reduced, and so is the height of the barrier (the height of the energy barrier against the conduction electrons) of the insulating layer (MgO) 207.

The metal layer (upper Mg) 208, on the other hand, is lower in barrier than the originally O-rich insulating layer (MgO) 207 even in the case where O atoms are diffused from the insulating layer (MgO) 207.

As a result, the average height of the barrier as a whole (intermediate layer 103) according to this embodiment is lower than in the absence of the metal layer (upper Mg) 208. According to this embodiment, therefore, the conduction electrons are easily passed through the barrier, so that the physical thickness corresponding to the same barrier resistance is larger than in the first and second reference examples.

With the increase in the physical thickness with the applied voltage and the barrier resistance remaining constant, the electric field in the barrier is decreased, and the degeneration and breakdown of the barrier by the electric field are suppressed for an improved life length before dielectric breakdown. Alternatively, the barrier resistance can be reduced without reducing the physical thickness.

The extraneous Mg in the Mg-rich MgO is considered to pose no problem of the barrier characteristic including the life length before dielectric breakdown and the MR ratio. The reason is that since Mg is larger than MgO in lattice constant, the crystalline lattice is shrunk in the case where the extraneous O atoms are diffused from the insulating layer (MgO) 207 into the metal layer (upper Mg) 208 and the Mg-rich MgO barrier is formed.

The MgO in the Mg-rich MgO, like the underlying insulating layer (MgO) 207, becomes the MgO crystalline lattice having the bcc(001) structure. With the shrinkage of the crystalline lattice, on the other hand, the extraneous Mg atoms come to exist in the MgO crystalline lattice and share the valence electrons with the MgO crystalline lattice. The Mg atoms are heavier than the O atoms, and therefore, as compared with the extraneous O atoms in the O-rich MgO, the extraneous Mg atoms are harder to move in the MgO crystalline lattice and hence to deform the MgO crystalline lattice. Thus, the extraneous Mg atoms are isolated into Mg²⁺ ions but never become a trap source or a leak spot. Once this satisfactory Mg-rich MgO is formed in the boundary between the upper magnetic layer 209 and the insulating layer (MgO) 207, a trap source is more difficult to form in MgO than in the conventional O-rich MgO. Even in the case where the conduction electrons that have passed through the MgO barrier release the extraneous energy corresponding to the applied voltage, therefore, the trap generation by the particular energy is suppressed and the life length before dielectric breakdown improved.

The second effect shows that the intermediate layer 103 desirably has the film composition described below.

In the case where the intermediate layer 103 has a double-layer structure including the metal layer 208 and the insulating layer 207, a Mg-rich MgO layer is formed on the upper surface of the boundary between the intermediate layer 103 and the ferromagnetic layer 209. As a result, the metal comes to exist in the upper part (metal layer 208) of the intermediate layer 103 in a greater proportion than in the lower part (insulating layer 207) of the intermediate layer 103. More desirably, the metal exists in the upper part (metal layer 208) of the intermediate layer 103 in a proportion at least 1.001 times greater than in the lower part (insulating layer 207) of the intermediate layer 103 to produce a special effect.

In the case where the intermediate layer 103 has a triple-layer structure including the metal layers 208, 206 and the insulating layer 207, on the other hand, a Mg-rich MgO layer is formed on the upper surface of the boundary between the intermediate layer 103 and the ferromagnetic layer 209, while another Mg-rich MgO layer is formed on the lower surface of the boundary between the intermediate layer 103 and the ferromagnetic layer 205. As a result, the upper part (insulating layer 208) and the lower part (metal layer 206) of the intermediate layer 103 contain the metal in a greater proportion than the intermediate part (insulating layer 207) of the intermediate layer 103. More desirably, the upper part (metal layer 208) and the lower part (metal layer 206) of the intermediate layer 103 contain the metal in proportion at least 1.001 times more than the intermediate part (insulating layer 207) of the intermediate layer 103 to produce a special effect.

Considering the intermediate layer 103 as a whole, the addition of Mg to MgO causes the average metal content ratio of the intermediate layer 103 to approach a layer (Mg_{>1}O_{<1}) higher than the stoichiometric ratio. More desirably, the average metal content ratio of the intermediate layer 103 is at least 1.001 times greater in proportion than the stoichiometric ratio to produce a special effect.

FIG. 11 shows the [Mg]/[O] concentration ratio of the intermediate layer 103 as a whole according to the first and second reference samples and this embodiment. This embodiment (upper Mg 0.6) represents a case in which the upper Mg having the thickness of 0.6 nm is formed, while the thickness of the lower Mg according to this embodiment and the second reference example is 0.4 nm. The first and second reference examples correspond to FIGS. 1A and 1B, respectively.

FIG. 11 shows an example of the result of the physical analysis using energy dispersive X-ray spectroscopy (EDX). According to the EDX method, a sample is irradiated with an electron beam and the characteristic X-ray released from elements in the sample are analyzed under the sectional TEM (transmission electron microscope) thereby to quantify the elements.

As shown in FIG. 11, according to the embodiment having Mg on MgO, as compared with the first and second reference examples, the metal exists in a higher proportion and is considered to be nearer to a layer (Mg_{>1}O_{<1}) with a higher average metal content ratio of the intermediate layer 103 than the stoichiometric ratio.

The effects of the upper Mg shown in FIG. 11 are as follows:

As shown in FIG. 11, MgO in the first and second reference examples is rich with O. This is considered due to the fact that the O atoms lighter than the Mg atoms are more easily separated from the surface of the sputter target and the inner wall of the film-forming device and the concentration of the O atoms supplied to the substrate surface is higher than the concentration of the Mg atoms.

FIG. 9A shows the improvement of the MR ratio due to the O₂ processing of MgO. This is considered due to the fact that the O atom defect in the bcc(001) crystalline lattice of MgO has been repaired with O₂, and therefore, the leak spots are reduced. This processing of MgO in the oxidation atmosphere, however, has no effect of reducing the extraneous O atoms in MgO.

As long as the MgO formed on the substrate surface is rich in O, the extraneous O atoms liable to become negative ions make up an electron trap source by capturing electrons or a leak spot source passing the conduction electrons, thereby reducing the life length before dielectric breakdown or the MR ratio of MgO.

In the upper Mg 0.6 shown in FIG. 11, the relation [0]>[Mg] still holds, but the Mg concentration is more improved than in the first and second reference examples. This corresponds to the improvement of the life length before dielectric breakdown and the MR ratio due to the upper Mg. Specifically, a part of the extraneous O atoms in the O-rich MgO is stabilized as MgO, and therefore, the trap sources and leak spots are probably reduced.

Incidentally, the ideal MgO having the relation [Mg]>[O] can be formed by optimizing the MgO-forming conditions as rich in O and substantially in the relation Mg:O=1:1 and also by optimizing the various film-forming conditions such as the forming of the corresponding upper Mg, the processing in the oxidation atmosphere and the smoothing process.

[8] Application to Magnetic Random Access Memory

The magnetoresistive effect element 100 described above can be used as a storage element of a magnetic random access memory. The magnetic random access memory includes a plurality of memory cells each having the magnetoresistive effect element described above thereby to form a memory cell array.

For example, the lower wiring layer 101 shown in FIG. 2 is connected with a transistor, and by turning on this transistor, the current is supplied between the fixed magnetization layer 102 and the memory layer 104 of the magnetoresistive effect element 100.

Data can be written in the magnetic random access memory in any one of two methods, roughly speaking. According to one method called the magnetic field write method, the direction of magnetization of the memory layer 104 is reversed by a magnetic field generated with a current supplied to a write wiring arranged in the neighborhood of the magnetoresistive effect element 100. In the other method called the spin injection write method, a write current is supplied to the magnetoresistive effect element 100 and the conduction electrons arranged in the same spin direction by the fixed magnetization layer 102 are supplied to the memory layer 104 thereby to reverse the magnetization of the memory layer 104. According to this embodiment, the magnetoresistive effect element 100 is usable for both the magnetic field write method and the spin injection write method. The application to the latter, however, is more desirable and can produce the effects of this embodiment more easily.

In the spin injection write method, the directions of magnetization of the fixed magnetization layer 102 and the memory layer 104 are parallel or antiparallel with each other in accordance with the direction of the current flowing between the fixed magnetization layer 102 and the memory layer 104. For this reason, the direction of the current supplied is defined as described below.

In the case where “1” data is written, the current is supplied from the fixed magnetization layer 102 to the memory layer 104. In other words, electrons are injected from the memory layer 104 side to the fixed magnetization layer 102 side. As a result, the directions of magnetization of the fixed magnetization layer 102 and the memory layer 104 are opposite to and antiparallel with each other. This high resistance state Rap is defined as “1” data.

In the case where “0” data is written, on the other hand, the current is supplied from the memory layer 104 of the MTJ element MTJ toward the fixed magnetization layer 102. Specifically, electrons are injected from the fixed magnetization layer 102 side to the memory layer 104 side. As a result, the directions of magnetization of the fixed magnetization layer 102 and the memory layer 104 are arranged in the same direction and in parallel to each other. This low resistance state Rp is defined as “0” data.

In the read operation, the transistor connected to the lower wiring layer 101 shown in FIG. 2 is turned on, the bit line of the select cell is selected, and the read current is supplied which tunnels through the intermediate layer 103 of the magnetoresistive effect element 100. In the process, the joint resistance value varies in proportion to the cosine of the relative angles of magnetization between the fixed magnetization layer 102 and the memory layer 104, so that the tunnel magnetoresistive (TMR) effect is achieved in which in the case where the magnetization of the magnetoresistive effect element 100 is parallel (for example, “0” data), the resistance becomes low, while in the case where the magnetization of the magnetoresistive effect element 100 is antiparallel (for example, “1” data), on the other hand, the resistance is high. By reading the difference in resistance value, therefore, the “1” and “0” states of the magnetoresistive effect element 100 can be identified.

[b 9] Effects

With the magnetoresistive effect element 100 according to an embodiment of this invention, the metal layer 208 of Mg, for example, is formed on the insulating layer 207 of MgO. Also, the surface of the uppermost layer (ferromagnetic layer 205) of the fixed magnetization layer 102 is smoothed before forming the lowest layer (metal layer 206) of the intermediate layer 103. Also, after processing the surface of the insulating layer 207 in the oxidation atmosphere, the metal layer 208 is formed on the particular surface.

As a result, the boundary of the intermediate layer 103 with the upper ferromagnetic layer 209 is prevented from forming a trap source which would otherwise be formed due to the energy release by the conduction electrons, thereby making it possible to form a tunnel barrier high in smoothness with the oxygen atom defect repaired. Thus, a magnetoresistive effect element high in MR ratio and a withstanding voltage, long in the life length before dielectric breakdown and suppressed in generation of minority faulty elements with a low withstanding voltage can be realized.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetoresistive effect element comprising:
a first ferromagnetic layer formed above a substrate;
a second ferromagnetic layer formed above the first ferromagnetic layer;
a first metal oxide layer interposed between the first ferromagnetic layer and the second ferromagnetic layer; and
a second metal oxide layer interposed between the first metal oxide layer and the second ferromagnetic layer and in contact with a surface of the first metal oxide layer on the side of the second ferromagnetic layer, the second metal oxide layer containing the same metal element as the first metal oxide layer in a greater proportion than the first metal oxide layer.

2. The magnetoresistive effect element according to claim 1, further comprising:
a third metal oxide layer interposed between the first metal oxide layer and the first ferromagnetic layer and in contact with a surface of the first metal oxide layer on the side of the first ferromagnetic layer, the third metal oxide layer containing the same metal element as the first metal oxide layer in a greater proportion than the first metal oxide layer.

3. The magnetoresistive effect element according to claim 1,
wherein a thickness of the second metal oxide layer is 0.2 nm to 2 nm.

4. The magnetoresistive effect element according to claim 1,
wherein the first metal oxide layer and second metal oxide layer are formed of MgO.

5. A magnetic memory device comprising a memory cell provided with a magnetoresistive effect element as a memory element,
wherein the magnetoresistive effect element comprises:
a first ferromagnetic layer formed above a substrate;
a second ferromagnetic layer formed above the first ferromagnetic layer;
a first metal oxide layer interposed between the first ferromagnetic layer and the second ferromagnetic layer; and
a second metal oxide layer interposed between the first metal oxide layer and the second ferromagnetic layer and in contact with a surface of the first metal oxide layer on the side of the second ferromagnetic layer, the second metal oxide layer containing the same metal element as the first metal oxide layer in a greater proportion than the first metal oxide layer.

6. The magnetic memory device according to claim 5,
wherein the magnetoresistive effect element further comprises:
a third metal oxide layer interposed between the first metal oxide layer and the first ferromagnetic layer and in contact with a surface of the first metal oxide layer on the side of the first ferromagnetic layer, the third metal oxide layer containing the same metal element as the first metal oxide layer in a greater proportion than the first metal oxide layer.

7. The magnetic memory device according to claim 5,
wherein a thickness of the second metal oxide layer is 0.2 nm to 2 nm.

8. The magnetic memory device according to claim 5,
wherein the first metal oxide layer and second metal oxide layer are formed of MgO.

9. The magnetoresistive effect element according to claim 1,
wherein the second metal oxide layer contains the same metal element in proportion 1.001 times more than the first metal oxide layer.

10. The magnetic memory device according to claim 5,
wherein the second metal oxide layer contains the same metal element in proportion 1.001 times more than the first metal oxide layer.
